(19) United States
(12) Patent Application Publication
(10) Pub. No.: US 2010/0304504 A1
(43) Pub. Date: Dec. 2, 2010

(54) PROCESS AND APPARATUS FOR FABRICATING MAGNETIC DEVICE

(75) Inventors: Sanjay Shinde, San Jose, CA (US); Yoshimitsu Kodaira, Tokyo (JP); Taroh Furumochi, Tokyo (JP)

Correspondence Address: FITZPATRICK CELLA HARPER & SCINTO, 1290 Avenue of the Americas, NEW YORK, NY, 10104-3800, US

(73) Assignee: Canon ANELVA Corporation, Kawasaki-shi (JP)

(21) Appl. No.: 12/472,799

(22) Filed: May 27, 2009

(51) Int. Cl. H01L 21/00

(52) U.S. Cl. 438/3; 156/345.39; 257/E21.001

(57) ABSTRACT

Process and apparatus for fabricating a magnetic device is provided. Magnetic and/or nonmagnetic layers i n the device are etched by a mixed gas of a hydrogen gas and an inert gas such as N₂ with using a mask of non-organic material such as Ta. As results, in a studied example, a MTJ taper angle is nearly vertical.

### BACKGROUND OF THE INVENTION

1. Field of the Invention

The present invention relates to a process of fabricating a magnetic device, which includes a dry etching method. More specifically, the present invention relates to the dry etching method which is useful for micro processing for a film or a stack of films of magnetic material(s) (hereinafter the term ‘magnetic material’ is used for ferromagnetic, ferromagnetic, and antiferromagnetic material) such as FeNi, CoFe, FeMn, CoPt, CoFeB, PtMn, and IrMn.

2. Related Background Art

The random access memories such as MRAM (magnetic random access memory) and STRAM (spin transfer random access memory), that use magnetic materials have received attention as a memory which has the same level of high integration density as a DRAM and the same level of a high speed performance as an SRAM, and is nonvolatile and unlimitedly rewritable. Similarly, a thin-film magnetic head which constitutes a magnetic resistance device such as a GMR (giant magneto-resistance) and a TMR (tunneling magneto-resistance), a magnetic sensor and the like have been rapidly developed.

Up to now, an ion milling method has been often employed as an etching process for a magnetic material. However, since the ion milling method is a physical sputter etching process, it is difficult to selectively etch different materials. The ion milling also has a problem that after etching, the profile has a tapered or skirt-like shape. Therefore, the ion milling method has not been suitable particularly for a manufacture of an MRAM having a large capacity, for which a fine processing technology is needed. Additionally, the ion milling has difficulty in processing a substrate having a large area of 300 mm with a high uniformity and is therefore difficulty in enhancing yield, under present circumstances.

In place of such an ion milling method, technologies are starting to be introduced which have been nurtured in a semiconductor industry. Among the technologies, etching processes are positively developed, which use an NH₃+CO-based gas that is effective for processing a ferromagnetic material without forming after-corrosion (Japanese Patent Application Laid-Open No. H8-253881), and which use a CH₃OH gas (Japanese Patent Application Laid-Open No. 2005-42143). However, the etching processes by using these reactant gases cause an oxidation reaction on the processed surface of the magnetic material, and accordingly caused a problem that the magnetic properties were deteriorated after the magnetic material was processed

A conventional MRAM device or TMR sensor device has had a comparatively large junction area, so that a damaged layer due to the oxidation of the processed surface on the magnetic material has not given a large influence to the magnetic properties. However, as the junction area becomes smaller, the influence due to the oxidation layer (damaged layer) formed on the processed surface cannot be neglected. As the micro processing will further progress in the future, this problem will increasingly give an important influence to the magnetic properties, so that normal device characteristics may not be obtained

### SUMMARY OF THE INVENTION

An object of the present invention is to provide a process of fabricating a magnetic device, which uses a dry etching method that can reduce an etching damage that can deteriorate the magnetic characteristics by using a gas which does not oxidize the processed surface of a magnetic material, when etching the magnetic material while using a non-organic material as a mask material, and to provide an apparatus therefore.

In order to achieve the above described object, this invention proposes a dry etching method for etching a magnetic material(s) by using a mixture gas of a carbon hydride gas and an inert gas, and by using a mask made from a non-organic material.

An example of the above described etching gas is a mixture gas of ethylene (C₂H₄) gas and nitrogen (N₂) gas.

A mask made from the non-organic material can employ a mask material made of a single film or a stacked film of any of Ta, Ti, Al and Si, or a mask material made from a single film or a stacked film of an oxide or a nitride of any of Ta, Ti, Al and Si.

A mask material can employ, for instance, a single film or a stacked film made from any of Ta, Ti, Al and Si which are single elements The mask material also can employ a single film or a stacked film made from Ta oxide, Ti oxide, Al oxide such as Al₂O₃, Si oxide such as SiO₂, TaN, TiN, AlN, SiN and the like, which are an oxide or a nitride of any of Ta, Ti, Al and Si.

In the above described dry etching method which is adopted in the present invention, the magnetic material is etched while the temperature of the magnetic material is kept desirably in a range of 250° C. or lower. This is because of preventing the magnetic thin film which is extremely thin from receiving an unnecessary thermal damage. The more preferable temperature is in a range from 20 to 100° C. In the above described dry etching method which is adopted in the present invention, the magnetic material is etched desirably in a vacuum in a range from 0.005 Pa to 10 Pa. This pressure range can process the magnetic material with excellent anisotropy. In the above described dry etching method according to the present invention an inert gas is added to an etching gas as an additive gas Any of these gases may be added singly or in an optional combination with gases in the group. It is desirable to add the inert gas in a range of 10% by volume or more but 95% by volume or less into the etching gas. The inert gas to be defined here includes nitrogen gas in addition to a rare gas such as He, Ar, Ne, Xe and Kr.

When a magnetic material is etched by using a dry etching method which is adopted in the present invention and a mask made from a non-organic material, the necessity for after-corrosion treatment is eliminated, and the corrosion resistance of an etching apparatus is not necessary to be particularly considered.

In addition, the dry etching method according to the present invention can reduce an etching damage which occurs when the magnetic material is etched by using the mask made from the non-organic material, and results in deteriorating magnetic characteristics by inhibiting the processed surface from being oxidized during the etching process.

Thus, the present invention can provide a dry etching method which is useful for micro processing for a ferromagnetic thin film made of a single film or a stacked film of an Fe—Ni-based alloy, a Co—Fe-based alloy, an Fe—Mn-based alloy, a Co—Pt-based alloy, an Ni—Fe—Cr-based alloy, a Co—Cr-based alloy, a Co—Pt-based alloy, a Co—Cr—Pt-based alloy, a Co—Pd-based alloy and a C—Fe—B-based alloy.

### BRIEF DESCRIPTION OF THE DRAWINGS

FIG. 1 is a schematic block diagram of an etching apparatus which can be used in a method according to the present invention.

FIG. 2A is a view illustrating an exemplary embodiment of an magnetic tunnel junction (MTJ) device structure according to the present invention, which is not yet etched.

FIG. 2B is a view in which a Ta mask is formed on the structure of FIG. 2A.

FIG. 2C is a view illustrating an exemplary embodiment of an MTJ device which is fabricated through etching treatment according to the present invention with the use of the Ta mask of FIG. 2B.

FIG. 3A is a view of an emission spectral analysis when an electric discharge was caused in a gas according to the present invention.

FIG. 3B is a view of an emission spectral analysis when an electric discharge was caused in CH₃OH gas.

FIG. 4 is an SEM image of an MTJ device which has been processed with a method according to the present invention.

### DESCRIPTION OF THE PREFERRED EMBODIMENTS

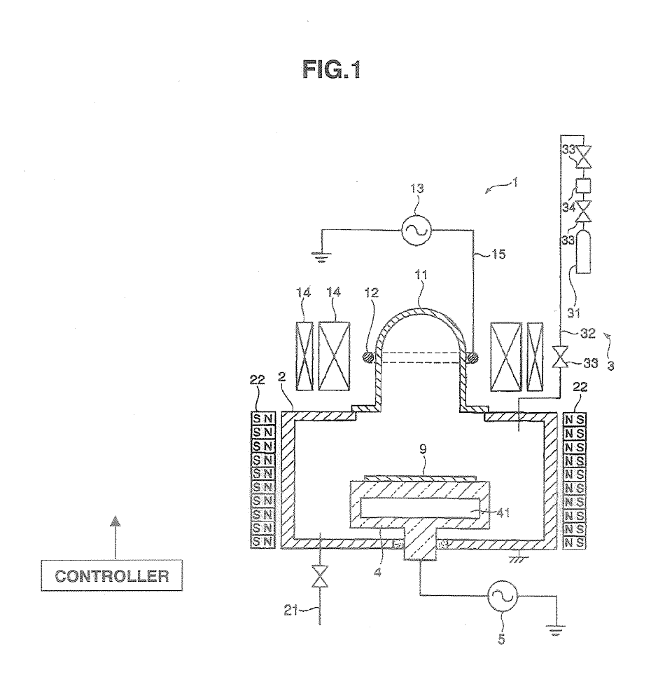

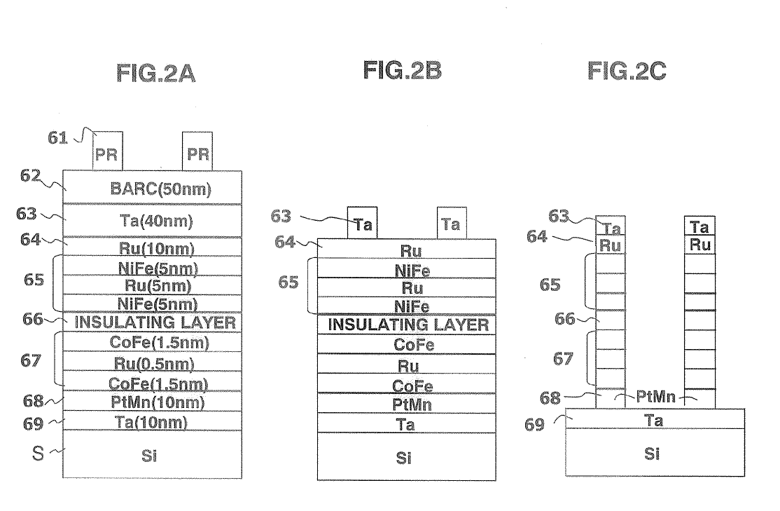

The exemplary embodiment according to the present invention uses an etching apparatus which is provided with an ICP (Inductive Coupled Plasma) source as illustrated in FIG. 1. In the present apparatus, an MTJ device as illustrated in FIG. 2A to FIG. 2C is etched by using an etching gas which is a mixture gas of ethylene (C₂H₄) and nitrogen (N₂) and a Ta mask.

FIG. 2A to FIG. 2C illustrate one example of a basic structure of an MTJ (magnetic tunnel junction) device. The MTJ device in a state having a structure as illustrated in FIG. 2A is introduced into an etching apparatus. The structure is formed specifically by stacking a Ta layer 69 on an Si substrate S in FIG. 2A; a antiferromagnetic layer 68 made from PtMn, a magnetic pinned layer 67 made from three layers of CoFe/Ru/CoFe, an insulating layer 66 made from magnesium oxide, alumina or the likes and a magnetic free layer 65 made from NiFe/Ru/NiFe thereon; and further an upper electrode layer 64 made from Ru, a Ta layer 63 which is a metal mask layer, an antireflection layer (BARC layer) 62 thereon, and a photoresist layer (PR layer) 61 formed thereon so as to have a predetermined pattern [FIG. 2A]. The film structure and materials of the MTJ device are not limited to the one illustrated in FIG. 2A, and may include a TMR film which is constituted at least by an insulating layer and ferromagnetic layers formed on both sides thereof For instance, the ferromagnetic layer which constitutes a magnetic free layer and a magnetic pinned layer may be a single film or a stacked film of an Fe—Ni-based alloy, a Co—Fe-based alloy, an Fe—Mn-based alloy, a Co—Pt-based alloy, an Ni—Fe—Cr-based alloy, a Co—Cr-based alloy, a Co—Pt-based alloy, a Co—Cr—Pt-based alloy, a Co—Pd-based alloy and a Co—Fe—B-based alloy, in addition to the above described NiFE and CoFe.

The MTJ device having a structure illustrated in FIG. 2A was processed so as to have a predetermined pattern as illustrated in FIG. 2B, by etching a Ta layer 63 by using a CF₄ gas and a PR layer 61 as a mask. This process was performed specifically in the following way.

The inside of a vacuum container 2 illustrated in FIG. 1 was exhausted by an exhaust system 21, and was kept at a predetermined temperature with the use of a temperature control mechanism 41 after the steps of: opening an unshown gate valve; transporting a wafer 9 into the vacuum container 2, which is to be an MTJ device having a structure as illustrated in FIG. 2A and has TMR films stacked thereon; and making a substrate holder 4 hold the wafer 9. Subsequently, a gas introduction system 3 was operated, and an etching gas (CF₄) was introduced into the vacuum container 2 from a bomb 31 which was filled with CF₄ gas and is not shown in FIG. 1 at a predetermined flow rate through a bulb 33 and a flow rate controller 34. A pipe 21 is an exhaust system. An introduced etching gas spreads into a dielectric wall container 11 through the vacuum container 2. Here, a plasma source 1 was operated. The plasma source 1 is constituted by: the dielectric wall container 11 which is hermetically connected to the vacuum container 2 so that the inner spaces communicate with each other; an antenna 12 of one turn for generating an induction field in the dielectric wall container 11; a high-frequency power source 13 for plasma, which is connected with the antenna 12 through a transmission line 15 and an unshown matching box, and generates a high-frequency power (source power) to be supplied to the antenna 12; and an electromagnet 14 for generating a predetermined magnetic field in the dielectric wall container 11. When the high-frequency power which has been generated by the high-frequency power source 13 for plasma has been supplied to the antenna 12 through the transmission line 15, an electric current flows in the antenna 12 of one turn. As a result, a plasma is formed in the inner part of the dielectric wall container 11. A large number of magnets for a side wall 22 are arranged in the outer periphery of the side wall of the vacuum container 2 so that the magnets have different poles on their faces opposing to the side wall of the vacuum container 2 from each of adjacent magnets. Thereby, a cusp magnetic field is continuously formed in a peripheral direction along the inner face of the side wall of the vacuum container 2, and prevents the plasma from spreading to the inner face of the side wall of the vacuum container 2. At this time, a high-frequency power source for bias 5 is operated at the same time, and a self bias voltage which is such a voltage as to form a negative direct current is applied to a wafer 9 which is an object to be etched, and controls an ion energy incident on the surface of the wafer 9 from the plasma. The plasma which has been formed in the above described way spreads into the vacuum container 2 from the dielectric wall container 11, and reaches the vicinity of the surface of the wafer 9. At this time, the surface of the wafer 9 is etched.

The above etching process for forming the Ta layer 63 was conducted with the use of CF₄ and the PR layer 61 under the following conditions, for instance
flow rate of etching gas (CF₄): 50 sccm
source electric power: 500 W
bias electric power: 70 W
pressure in vacuum container 2: 0.8 Pa
temperature of substrate holder 4: 40° C.

Subsequently, layers 64 to 69 including a TMR film were etched by using a mixture gas of a carbon hydride gas and an inert gas as an etching gas and by using the Ta layer 63 which had been formed in the above described process as a mask, and were processed so as to have a predetermined pattern as illustrated in FIG. 2C.

This process was conducted also with the use of an etching apparatus which was equipped with an ICP plasma source as illustrated in FIG. 1, but an introduction system of the CF₄ gas in the above described process was switched to an unshown gas introduction system by an unshown gas switching mechanism. The mixture gas of the carbon hydride gas and the inert gas which does not oxidize the magnetic material was introduced into the vacuum container 2 at a predetermined flow rate through a flow rate controller, and was etched in a similar way to the above described process. The MTJ device was thus obtained.

Usable carbon hydride gases include: a gas of a carbon hydride having an alkylene group such as ethylene (C₂H₂) and propylene (C₃H₆), and a gas of a carbon hydride having an ethylene group such as ethane, propane and butane.

Usable inert gases (occasionally, hereinafter referred to as “additive gas”) include N₂ gas and a gas of He, Ar, Ne, Xe, Kr and the like, for instance. The gases can be used alone or in a form of a mixture.

A process for fabricating a magnetic device according to the present invention mainly employs a technique of extracting the inert gas ion onto an article to be processed, and a reaction of depositing a carbon compound originating from a carbon hydride gas on the surface to be processed to selectively etch the layers. In other words, when a carbon compound deposits on a mask layer that is hard to be physical-sputtered, the mask layer is changed into a plane that is more hardly etched, which produces a difference of an etching rate between a mask layer and a magnetic layer. Thereby, the layers are selectively etched, and the process according to the present invention can process the layers into a predetermined shape without causing the deterioration of the device due to the oxidation and the like.

Accordingly, the optimum additive amount varies depending on the type of each additive gas, but when the additive gas generally in a range of 10% by volume or more but 95% by volume or less is added with respect to the whole amount of the etching gas, the mixture is usable When the amount of the additive gas is less than 10% by volume, carbon originating from the carbon hydride gas deposits on the surface of the magnetic material during the etching process, so that the magnetic material cannot be etched On the other hand, when the amount of the additive gas exceeds 95% by volume, the difference of the etching rate between the mask layer and the magnetic layer becomes small, which degrades the selectivity of etching.

In the above, a preferred embodiment according to the present invention was described However, the present invention is not limited to the above described embodiment but can be modified into various forms in a technological range grasped from the scope of the claims.

For instance, an etching apparatus is not limited to an ICP-type plasma apparatus having an antenna of one turn as illustrated in FIG. 1, but can employ a helicon-type plasma apparatus which is referred to as a so-called high-density plasma source, a two-frequency excitation parallel plate type plasma apparatus, a micro wave type plasma apparatus and the like. The present invention can be applied also to RIBE (reactive ion beam etching) The present invention is not also limited to a TMR devices but can be applied to a GMR device as well. The present invention can also be used for fabricating a magnetic sensor device as well

The above described etching gas of ethylene (C₂H₄) and nitrogen (N₂) gas according to the present invention was subjected to a plasma emission spectral analysis. The etching gas of methanol (CH₃OH) which is used in a conventional art, was also subjected to the plasma emission spectral analysis similarly, and the results were compared.

(Plasma Emission Spectral Analysis of Etching Gas According to the Present Invention)
flow rates of ethylene (C₂H₄) and nitrogen (N₂) of etching gas: 18 sccm/12 sccm
source electric power: 1,800 W
bias electric power: 1,600 W
pressure in vacuum container 2: 1.0 Pa

(Plasma Emission Spectral Analysis of CH₃OH of Etching Gas)
flow rate of etching gas (CH₃OH gas): 15 sccm
source electric power 1,500 W
bias electric power: 1,300 W
pressure in vacuum container 2: 0.4 Pa

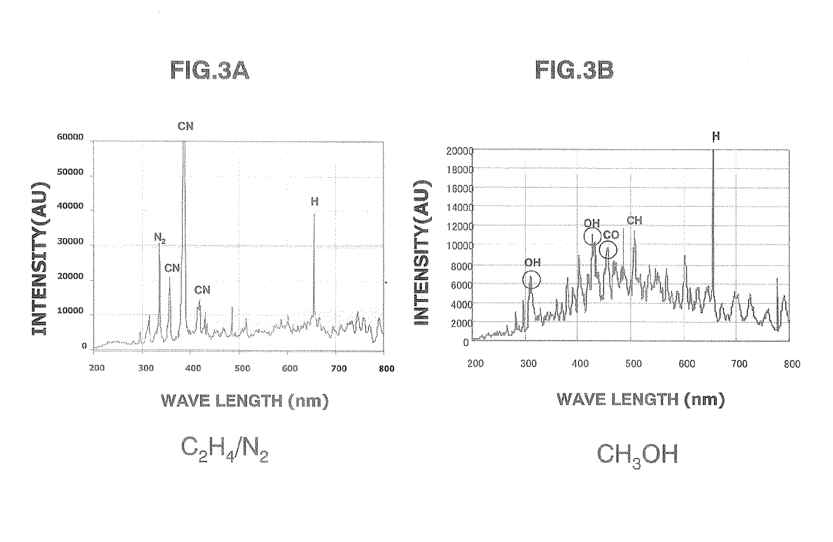

The comparison results are illustrated in FIG. 3A and FIG. 3B. A plasma spectral in FIG. 3B, which has been obtained by a plasma emission spectral analysis of CH₃OH gas, shows an emission spectrum in which O, OH and the like that promotes oxidation. These groups are considered to have been formed by the decomposition of CH₃OH. On the other hand, in a plasma emission spectrum of C₂H₄ and N₂ gases in FIG. 3A, many peaks of CH, CH and N occur but the peaks of O and OH do not occur. Accordingly, it was found that such reactive species as to oxidize the surface to be processed are not formed during the etching treatment of a magnetic material with the use of the plasma of the C₂H₄ and N₂ gases.

Etching characteristics were compared and examined between the case in which the device has been etched with a dry etching method according to the present invention, and the case in which the device has been etched with the use of a CH₃OH-based gas.

An MTJ device illustrated in FIG. 2 was etched by using an apparatus illustrated in FIG. 1, and the etching characteristics were compared.

Conditions in the process of the comparison test are as follows respectively

(Method of the Present Invention)
flow rates of ethylene (C₂H₄) and nitrogen (N₂) of etching gas: 21 sccm/9 sccm
source electric power: 1,800 W
bias electric power: 1,600 W
pressure in vacuum container 2: 1.0 Pa
temperature in substrate holder 4: 40° C.

### COMPARATIVE EXAMPLE

flow rate of etching gas (CH₃OH gas): 15 sccm
source electric power: 1500 W
bias electric power: 1,300 W
pressure in vacuum container 2: 0.4 Pa
temperature in substrate holder 4: 40° C.

The result of this comparative test was summarized in the following Table.

TABLE 1
Comparison table of etching characteristics

| | C₂H₄ + N₂ | CH₃OH |
|---|---|---|
| NiFe etching rate | 44.6 | 48.6 |
| [nm/min] | | |
| selectivity | 11 | 12.6 |
| NiFe/Ta | | |
| MTJ taper angle | 84 | 80 |

As for an etching rate for NiFe, the uniformity within plane of the etching rate and a selectivity ratio of NiFe to a Ta mask, etching characteristics of ethylene (C₂H₄) and nitrogen (N₂) according to the present invention showed approximately equal values to etching characteristics of methanol (CH₃OH). As for the etched shape of the MTJ device, an etching process using ethylene (C₂H₄) and nitrogen (N₂) according to the present invention provided a further perpendicular MTJ taper angle compared to that of the etching process using methanol (CH₃OH). This shows that the etching process according to the present invention is effective in the case where the size of the MTJ device becomes smaller along with the tendency of the miniaturization of a device in the future.

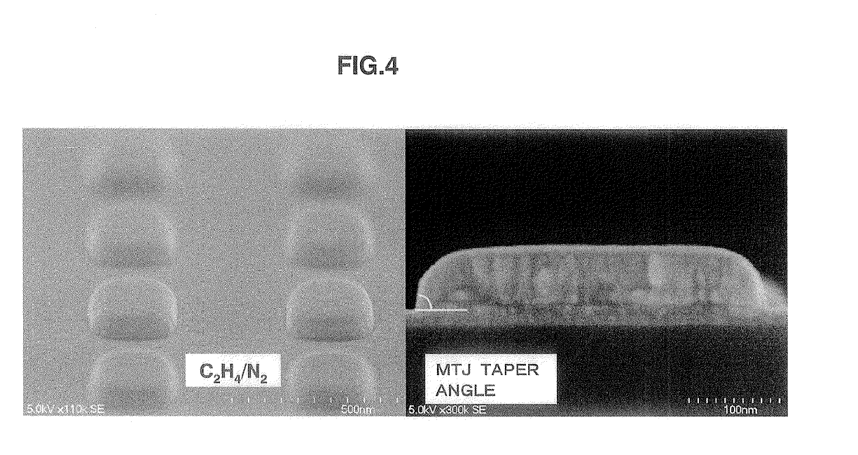

FIG. 4 illustrates an image (left) that is obliquely viewed from an upper part and a section image (right) of an SEM image of the shape of an MTJ device which has been obtained with an etching process using ethylene (C₂H₄) and nitrogen (N₂) according to the present invention. The etching process did not cause redeposition on the side wall and also did not form a residue on the etched surface, and provided an adequate etched shape. Furthermore, the MTJ device did not cause corrosion even after the etching treatment.

A test was carried out in order to examine the lower limit of the additive amount while using various additive inert gases. An additive amount when the etching rate became lower than a predetermined value due to the deposition of an organic material onto a magnetic material was determined by using an ethylene gas as a carbon hydride gas, and the additive amount was assumed to be the lower limit.

As a result, when the additive amount was lower than 15% by volume in the case of nitrogen gas, was lower than 25% by volume in the case of Ar gas, and was lower than 45% by volume in the case of He gas, the organic material deposited on the magnetic material. From the result, it was proved that a process of using nitrogen gas can reduce the used amount of the gas for obtaining a necessary etching rate and provide a preferable result.

It has been found that the above mentioned numbers for the lower limit of the additive gases also depend on the other process conditions used such as ethylene gas flow, chamber pressure, source power, bias power and others. Therefore, it is possible to have different limits for the different process conditions For examples use of another carbon hydride gas will have different lower limits for the additive gas.

The magnetization loss of a NiFe film due to etching process was also examined for the etching process using ethylene (C₂H₄) and nitrogen (N₂) according to the present invention and compared with the CH3OH process It was found that the magnetization change in comparison to the starting (not etched) films after ethylene (C₂H₄) and nitrogen (N₂) process according to the present invention was much smaller than the change after CH₃OH process.

Additionally, it has been observed that the ethylene (C₂H₄) and nitrogen (N₂) process according to the present invention can also etch materials that are not magnetic Examples include—Oxides such as SiO2, Al2O3, MgO, Nb2O5, ZrO2, NiO, PrCaMnO, Cr doped SrZrO3, V doped SrZrO3, PbZrTiO3, CuO, LaNiO, HfOx, BiOx, and the like; Single element materials such as Si, Ru, Cu, Fe, Cr, Ni, Pt, Au, Ir, Os, Re and the like; Alloy materials such as Cu—N alloys, Pt—Mn alloys, Ir—Mn alloys, Ni—Fe—Cr alloys, Ni—Cr alloys, and the like. Therefore, the present invention is also related to etching of single layer films or the stack of films comprised of nonmagnetic and/or magnetic materials. For example, the process described in the present invention is applicable to technology of patterned magnetic recording media (ex. BPM (Bit Patterned Media), DTM (Discrete Track Media)) and the like.

What is claimed:

1. A process of fabricating a magnetic device comprising:
preparing a structure including at least one magnetic layer or diamagnetic layer; and
processing the structure by a plasma of a mixed gas of a hydrocarbon gas and an inert gas to dry-etch the magnetic layer or diamagnetic layer using a mask of non-organic material.

2. The process according to claim 1, wherein the hydrogen in the gas has alkaline group.

3. The process according to claim 1, wherein the inert gas includes a nitrogen gas, or a gas of He, Ne, Ar, Kr, or the like.

4. The process according to claim 1, wherein the mixed gas Includes ethylene gas and nitrogen gas.

5. The process according to claim 1, wherein the mask is a single layer or multilayer, comprising Ta, Ti, Al or Si, or oxide of Ta, Ti, Al or Si.

6. The process according to claim 1, wherein the mixed gas includes inert gas in the range of 10 volume % to 95 volume % to the whole volume of the mixed gas.

7. Apparatus for fabrication a magnetic device comprising:
a film forming unit for forming a magnetic layer or diamagnetic layer on a substrate; and
a dry etching unit comprising plasma generating means provided with a chamber, a substrate holder within the chamber, gas introducing means for introducing a gas into the chamber, plasma generating means for generating a plasma of gas, bias application means for extracting ions from the gas plasma and directing the extracted ions to the substrate holder and a controller,
wherein said controller controls the dry etching unit to introduce a mixed gas of a hydrogen gas and an inert gas into the chamber by the gas introducing means generates the plasma of the introduced gas by the plasma generating means and extract inert ions from the gas plasma and directs the extracted inert gas to the substrate holding means.
